(19) United States
(12) Patent Application Publication
(10) Pub. No.: US 2025/0389786 A1
(43) Pub. Date: Dec. 25, 2025

(54) DETERMINING DEGRADATION OF AN ELECTRICAL DEVICE

(71) Applicant: EATON INTELLIGENT POWER LIMITED, Dublin 4 (IE)

(72) Inventors: Webb L. BURGESS, Raleigh, NC (US); Mayura MADANE, Pune, Maharashtra (IN); Aditee BAPAT, Pune Maharashtra (IN); Fiaz SHAIK, Andhra Pradesh (IN); Hardik MUNJAL, Haryana (IN); Raksha Rao KARAYA, Toronto (CA)

(21) Appl. No.: 18/879,292

(22) PCT Filed: Sep. 7, 2022
(86) PCT No.: PCT/EP2022/025416

§ 371 Date: Dec. 27, 2024

(30) Foreign Application Priority Data
Jun. 29, 2022 (IN) 202211037361

(51) Int. Cl. G01R 31/40; H02J 9/06

(52) U.S. Cl. CPC G01R 31/40; H02J 9/06

(57) ABSTRACT

Some embodiments relate to determining degradation of an electrical device, such as an Uninterruptible Power Supply (UPS) device. The invention includes retrieving historical service data, for a set of electrical devices, that includes historical sensor data indicative of environmental conditions in the vicinity of the electrical devices during operation, including measured temperature and humidity, and historical degradation data indicative of degradation of the electrical devices. The invention includes using the historical sensor data to determine historical values of degradation parameters indicative of electrical device degradation caused by environmental conditions, and using the historical values and the historical degradation data to determine a threshold value for each degradation parameter above which an unacceptable level of degradation occurs. The determined threshold values are used to determine whether an unacceptable level of degradation is occurring during operation of the electrical device.

### CROSS-REFERENCE TO RELATED APPLICATIONS

This application is a national phase filing under 35 C.F.R. § 371 of and claims priority to PCT Patent Application No. PCT/EP2022/025416, filed on Sep. 7, 2022, which claims the priority benefit under 35 U.S.C. § 119 of Indian patent application Ser. No. 20/221,1037361, filed on Jun. 29, 2022, the contents of which are hereby incorporated in their entireties by reference.

### TECHNICAL FIELD

The presently disclosed subject matter relates to determining degradation of an electrical or electronic device, such as an Uninterruptible Power Supply (UPS) device and, in particular, to determining degradation caused by environmental conditions in which the electrical device operates.

### BACKGROUND

An Uninterruptible Power Supply (UPS) is used for handling power interruptions and ensuring the delivery of quality power to electrical systems connected downstream. In particular, a UPS (or UPS device) provides emergency power to an electrical load or system when a main source of power fails or is otherwise unavailable. A UPS may store energy in batteries that can provide an instantaneous power supply upon mains power failure.

For critical applications—i.e. applications in which a reliable source of power is critical—the cost of unplanned downtime is high. Such applications include data centres, electrical equipment in hospitals, telecommunications equipment, etc. Degradation of UPSs such as battery-related degradation contribute to a significant number of downtime events in data centres and other applications.

It is therefore desirable to be able to properly maintain UPSs and batteries in order to improve the longevity of their components and minimise the number of unplanned downtime events. Ambient conditions or environmental conditions in the vicinity of a UPS can have a significant impact on its lifespan. Environmental conditions such as temperature or humidity local to the UPS can lead to corrosion of UPS electrical and electronic components, and degrade battery life.

As such, one or more sensors may be installed in the vicinity of a UPS to monitor environmental conditions such as temperature and humidity around the UPS. Known solutions for monitoring environmental conditions can fail to accurately detect environmental conditions that lead to UPS component degradation, leading to unplanned downtime events and/or false alarms. This can also be the case when monitoring environmental conditions that lead to degradation of other types of electrical or electronic devices/components.

It is against this background to which the presently disclosed subject matter is set.

### SUMMARY OF THE DISCLOSURE

According to an aspect of the presently disclosed subject matter there is provided a computer-implemented method for determining degradation of an electrical or electronic device. The method comprises retrieving historical service data for a set or fleet of one of more electrical or electronic devices. The historical service data includes, for each electrical or electronic device in the set: historical sensor data indicative of environmental conditions in the vicinity of the respective electrical or electronic device during operation, the sensor data including data indicative of at least measured temperature and measured humidity; and, historical degradation data indicative of degradation of the respective electrical or electronic device. The method comprises determining, based on the historical sensor data, historical values of one or more degradation parameters that are indicative of electrical or electronic device degradation caused by environmental conditions. The method comprises determining, based on the historical values of the one or more degradation parameters and on the historical degradation data, a threshold value for each degradation parameter, the threshold value being a value of the respective degradation parameter above which an unacceptable level of degradation occurs. The method comprises using the determined one or more threshold values to determine whether an unacceptable level of degradation is occurring during operation of the electrical or electronic device.

Using the determined one or more threshold values may comprise: receiving, from at least one sensor in the vicinity of the electrical or electronic device, sensor data indicative of environmental conditions in the vicinity of the electrical or electronic device, the sensor data including data indicative of at least measured temperature and measured humidity; determining, based on the received sensor data, a value of each of the degradation parameters; and, comparing each determined value against the respective threshold value to determine whether an unacceptable level of degradation is occurring.

In some examples, an unacceptable level of degradation may be determined to be occurring if at least one of the determined values exceeds the respective threshold value. In other examples, a prescribed number, e.g. above one, of the determined values may need to exceed the respective threshold values to conclude that an unacceptable level of degradation is occurring.

Prior to determining the values of each of the degradation parameters, the method may comprise applying one or more data filtering processes to the received sensor data, the values of each of the degradation parameters being determined based on the filtered data.

The one or more data filtering processes may comprise removing unfeasible data included in the received sensor data.

The one or more data filtering processes may comprise applying a low pass Butterworth filter to the received sensor data.

The received sensor data may comprise asynchronously sampled data. The one or more data filtering processes may comprise: prior to applying the low pass Butterworth filter, appending the received sensor data to a padding data signal comprising non-uniform sampled data to obtain a combined data signal, the low pass Butterworth filter being applied to the combined data signal; and, after applying the low pass Butterworth filter, removing the output response from the low pass Butterworth filter corresponding to the padding data signal prior to determining the values of each of the degradation parameters.

Prior to determining the historical values of each of the degradation parameters, the method may comprise applying one or more data filtering processes to the retrieved historical sensor data, the historical values of each of the degradation parameters being determined based on the filtered data.

The one or more degradation parameters may include one or more real-time degradation parameters. The one or more degradation parameters may include a dew point temperature. The one or more degradation parameters may include an equilibrium moisture content. The one or more degradation parameters may include a difference between the dew point temperature and the measured temperature.

The one or more degradation parameters may include at least one cumulative degradation parameter indicative of cumulative electrical or electronic device degradation over a defined time period caused by environmental conditions over the defined time period.

Determining the value of each cumulative degradation parameter may comprise: retrieving sensor data received from the at least one sensor in the vicinity of the electrical or electronic device over the defined time period; determining values of a real-time degradation parameter over the defined time period based on the retrieved sensor data; and, integrating the real-time degradation parameter values with respect to time to determine the associated cumulative degradation parameter value.

The at least one parameter indicative of cumulative electrical or electronic device degradation may include one or more of: cumulative temperature over the defined time period; cumulative humidity over the defined time period; cumulative dew point temperature over the defined time period; and, cumulative equilibrium moisture content over the defined time period.

The method may be implemented by one or more processors located remotely from the electrical or electronic device.

If it is determined that an unacceptable level of degradation is occurring during operation of the electrical or electronic device, then the method may comprise generating an alarm signal.

The alarm signal may be output to an operator of the electrical or electronic device. Optionally, the alarm signal may cause audio, visual and/or haptic feedback to be output to the operator. Alternatively, or in addition, the alarm signal may cause a data record to be created in a database.

If it is determined that an unacceptable level of degradation is occurring during operation of the electrical or electronic device, then the method may comprise generating a control signal to control one or more devices for mitigating the occurrence of electrical or electronic device degradation. Optionally, the control signal causes an air conditioning unit in the vicinity of the electrical or electronic device to activate.

The electrical or electronic device may be an Uninterruptible Power Supply (UPS) device (or, simply, a UPS).

The electrical or electronic device may be a battery. Optionally, the battery is for providing power to a UPS.

The electrical or electronic device may be one or more components of a data centre. Optionally, the components include a transformer, switchgear, and/or one or more hard disks.

The electrical or electronic device may be an electrical substation in a manufacturing plant.

According to an aspect of the presently disclosed subject matter there is provided a computer-implemented method for determining degradation of an electrical or electronic device. The method may comprise receiving, from at least one sensor in the vicinity of the electrical or electronic device, sensor data indicative of environmental conditions in the vicinity of the electrical or electronic device, the sensor data including data indicative of at least measured temperature and measured humidity. The method may comprise determining, based on the received sensor data, values of one or more degradation parameters that are indicative of electrical or electronic device degradation caused by environmental conditions. The method may comprise comparing each determined value against a respective defined threshold value to determine whether an unacceptable level of degradation is occurring. The one or more degradation parameters may include at least one of: a dew point temperature; an equilibrium moisture content; and, a difference between the dew point temperature and the measured temperature.

According to an aspect of the presently disclosed subject matter there is provided a computer-implemented method for determining degradation of an electrical or electronic device. The method may comprise receiving, from at least one sensor in the vicinity of the electrical or electronic device, sensor data indicative of environmental conditions in the vicinity of the electrical or electronic device, the sensor data including data indicative of at least measured temperature and measured humidity. The method may comprise determining, based on the received sensor data, values of one or more degradation parameters that are indicative of electrical or electronic device degradation caused by environmental conditions. The method may comprise comparing each determined value against a respective defined threshold value to determine whether an unacceptable level of degradation is occurring. The one or more degradation parameters may include at least one cumulative degradation parameter indicative of cumulative electrical or electronic device degradation over a defined time period caused by environmental conditions over the defined time period.

According to another aspect of the presently disclosed subject matter there is provided a non-transitory, computer-readable storage medium storing instructions thereon that when implemented by one or more computer processors cause the one or more computer processors to perform the method defined above.

According to another aspect of the presently disclosed subject matter there is provided a system for determining degradation of an electrical or electronic device. The system is configured to retrieve historical service data for a set of one of more electrical or electronic devices. The historical service data includes, for each electrical or electronic device in the set: historical sensor data indicative of environmental conditions in the vicinity of the respective electrical or electronic device during operation, the sensor data including data indicative of at least measured temperature and measured humidity; and, historical degradation data indicative of degradation of the respective electrical or electronic device. The system is configured to determine, based on the historical sensor data, historical values of one or more degradation parameters that are indicative of electrical or electronic device degradation caused by environmental conditions. The system is configured to determine, based on the historical values of the one or more degradation parameters and on the historical degradation data, a threshold value for each degradation parameter, the threshold value being a value of the respective degradation parameter above which an unacceptable level of degradation occurs. The system is configured to use the determined one or more threshold values to determine whether an unacceptable level of degradation is occurring during operation of the electrical or electronic device.

The system may comprise one or more computer processors configured to perform the functional steps to determine electrical or electronic device degradation, wherein the one or more computer processors may be remote from the electrical or electronic device.

### BRIEF DESCRIPTION OF THE DRAWINGS

Examples of the presently disclosed subject matter will now be described with reference to the accompanying drawings, in which:

FIG. 1 schematically illustrates a data centre including an Uninterruptible Power Supply (UPS) device for providing emergency power to electrical systems or components of the data centre, and illustrates a controller for determining degradation of the UPS device in accordance with an aspect of the presently disclosed subject matter;

FIG. 2 summarises the steps of a method performed by the controller of FIG. 1 to determine threshold values for one or more degradation parameters used to indicate degradation of the UPS device;

FIGS. 3(a) and 3(b) illustrate two experimental plots of humidity against time when a Butterworth filter is applied to asynchronously sampled humidity sensor data associated with the UPS device of FIG. 1; and,

FIG. 4 summarises the steps of a method performed by the controller of FIG. 1 to determine whether there is an unacceptable level of degradation of the UPS device.

### DETAILED DESCRIPTION

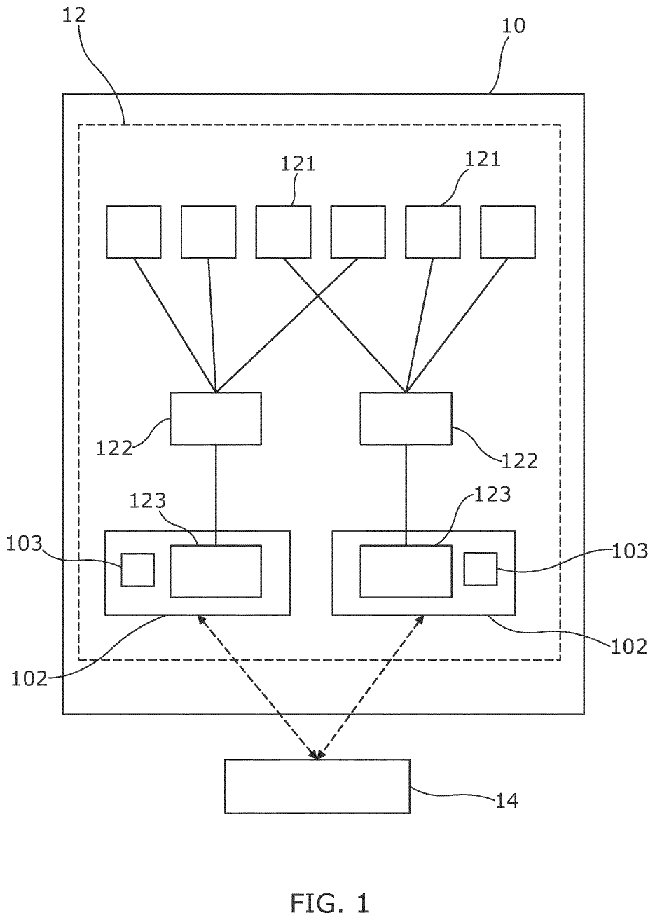

FIG. 1 is a schematic illustration of a data centre 10 that is used to house computer systems and associated electrical components. The data centre 10 may be in the form of a building, or a dedicated space within a building, for instance. The data centre 10 has an electrical power system 12 in which electrical power is supplied to systems and components 121 in the data centre 10.

The electrical equipment units or components 121 need to be provided with electrical power to operate or function. In the described example, the electrical equipment 121 may be located in a server room or space of the data centre 10. The electrical equipment units 121 in the server room may primarily include server machines (or, simply, servers) that provide services, e.g. processing or saving/storage services, to various client stations, e.g. computers. The electrical equipment units 121 may also include other server room equipment that requires electrical power, such as peripheral devices or hardware.

The electrical power system 12 may include a plurality of power distribution units (PDUs) 122 in the form of devices that distribute power from an input to a plurality of outlets of each PDU 122. PDUs are typically used for the distribution of power to equipment such as racks of computers and/or networking equipment in a data centre, i.e. the electrical equipment units 121 in the described example. The input of each PDU 121 may receive power from any suitable power source.

During normal operation of the electrical power system 12, the PDUs 122 may receive power from a mains power source (not shown). The PDUs 122 may receive power from other sources, e.g. a (backup) generator or other utility power source. In the described example, the electrical power system 12 includes one or more Uninterruptible Power Supply (UPS) devices 123 (or, simply, UPSs). Different ones of the PDUs 121 may receive power from different ones of the UPSs 123.

The UPSs 123 may be used to provide emergency power to the electrical equipment units 121, for instance if one or more mains power sources fails or is unavailable for any given reason. UPSs may typically be used for handling power interruptions and ensuring the delivery of quality power to electrical systems connected downstream. A UPS may in some examples provide non-emergency power to electrical equipment. A UPS may store energy in batteries that can provide an instantaneous power supply upon mains power failure.

The UPSs 123 include different components that have a finite lifespan. These include components such as batteries, capacitors, bus bars, leads, etc. In particular, the functionality/performance of components of the UPSs 123 may degrade over time until the UPS is no longer usable or it fails.

The ambient or environmental (operating) conditions in which a UPS operates can influence the rate at which component degradation occurs. In particular, improper or undesirable environmental conditions may lead to corrosion of the UPS electrical and/or electronic components and degrade battery life.

The UPSs 123 may be located in a cabinet 102, e.g. battery cabinet, in the server room or elsewhere. The cabinets 102 contain electrical equipment and may have no cooling fans present, meaning that environmental conditions in which the UPSs 123 operate may be undesirable, e.g. high temperature or high humidity.

One or more sensors 103 are provided to monitor the environmental or ambient conditions in which the UPSs 123 are operating. In particular, the sensors 103 are located in the vicinity of the UPSs 123 so as to monitor conditions local to the UPSs 123. In the described example, the sensors 103 are located in the battery cabinets 102 so that environmental conditions in the cabinets 102 may be monitored. The sensors 103 may in some examples be regarded as being part of the electrical power system 12.

In the described example, each UPS device 123 has one of the sensors 103 installed in its vicinity. Each sensor 103—for instance, which may be referred to as an Environment Monitoring Probe (EMP) sensor—is for measuring at least (local) temperature and (local) humidity around the respective UPS 123.

In known systems, such a sensor may monitor local temperature and humidity relative to respective predefined threshold values. These predefined threshold values may be set or derived from industry standards or literature. As such, they may not accurately reflect the environmental conditions (temperature and humidity) that actually cause degradation of components of a UPS being used in a particular context or for a particular application. This can result in unplanned downtime events without prior warnings if unacceptable degradation (including failure) is actually caused by lower ambient temperatures or humidity than is assumed by the predefined thresholds. On the other hand, false alarms may occur if the predefined thresholds are set at too low a value (such that the thresholds are breached, and alarms are triggered, at environmental operating conditions of the UPS which are not actually detrimental—to an unacceptable level—to the lifespan of the components).

Examples of the presently disclosed subject matter are advantageous in that threshold values for various environmental parameters—including temperature and humidity—are derived so as to more accurately reflect environmental conditions that are detrimental to the performance/lifespan of a UPS to an unacceptable extent, i.e. such that action may need to be taken, e.g. raise a notification or alarm. In particular, threshold values may be determined based on historical service data or field service data of a (training) set of UPSs, e.g. that operate in the field in different environmental conditions or in different contexts. The historical service data includes historical sensor data of at least measured temperature and humidity in the vicinity of the various UPSs in the set. The historical service data also includes historical degradation data indicative of component degradation of the UPSs in the set. The historical service data may therefore be used to automatically derive threshold values that more accurately reflect degradation modes or when component degradation becomes too high/unacceptably high.

Examples of the presently disclosed subject matter are advantageous in that they make use of the available sensor data to provide greater insights into when certain wear or damage modes of a UPS is occurring. Known systems may consider temperature and humidity in isolation relative to predefined threshold values as mentioned above. While temperature and humidity each indicate certain wear modes or conditions, other problematic operating conditions may not be identified based on such analysis. For instance, independent monitoring of these parameters does not provide a good depiction of condensation in the environment, where condensation can accelerate corrosion-related component degradation. Examples of the presently disclosed subject matter advantageously derive and consider a greater variety of ‘degradation parameters’ that are indicative of UPS device degradation caused by environmental conditions based on available sensor data (and optionally any other available data). This means that degradation caused by different types of operating or environmental conditions can be identified so as to reduce the amount of unplanned downtime caused by component degradation. In particular, these parameters can identify degradation based not only on instantaneous values of sensor data, but cumulative degradation or stress to UPS components over time.

Examples of the presently disclosed subject matter are advantageous in that they reduce the number of false alarms or missed alarms—indicative of unacceptably high levels of degradation —resulting from noisy data captured by sensors in the field. This is achieved via the use of specific data filtering techniques that will be described below. Furthermore, examples of the presently disclosed subject matter are advantageous in that data from a greater number of sensors may be readily handled as part of the degradation determination process, meaning that more accurate identification of when unacceptably high levels of degradation are occurring is possible. To address the associated issues of increased data storage and transmission requirements when more sensors are used, only some of the collected sensor data may be transmitted (wirelessly) and stored, e.g. when a significant enough change has occurred. This leads to asynchronous sampling of sensor data, which can lead to issues when analysing the data for the degradation determination. Examples of the presently disclosed subject matter are therefore advantageous in that they provide for accurate and quick analysis of asynchronously sampled data.

Returning to FIG. 1, there is a provided a system or controller 14 for monitoring the environmental conditions in which one or more of the UPSs 123 are operating, and for identifying or determining when a level of degradation or wear being suffered by the UPS 123 as a result of the detected environmental conditions reaches an unacceptable level.

The controller 14 may be located remotely from the UPS 123 and sensor 103, and may be located remotely from the data centre 10. For instance, the controller 14 may be a cloud-based controller. It will be understood, however, that the controller may be located locally in the data centre in different examples. The controller 14 includes an input for receiving sensor data from the sensors 103 (either directly or indirectly via a database storing the sensor data) and other data—e.g. historical sensor data-from different data sources such as databases storing such data, e.g. cloud-based storage. The controller 14 includes one or more computer processors for analysing the received data to derive appropriate degradation parameter thresholds and/or to determine when an unacceptable level of degradation is occurring based on received sensor data. The controller 14 also includes an output that can output alarm or notification signals based on the analysis performed by the processor, and may be configured to perform one or more control outputs based on the determinations.

The controller 14 may be in the form of, or include, any suitable computing device, for instance one or more functional units or modules implemented on one or more computer processors. Such functional units may be provided by suitable software running on any suitable computing substrate using conventional or customer processors and memory. The one or more functional units may use a common computing substrate (for example, they may run on the same server) or separate substrates, or one or both may themselves be distributed between multiple computing devices. A computer memory may store instructions for performing the methods to be performed by the controller 14, and the processor(s) may execute the stored instructions to perform the methods.

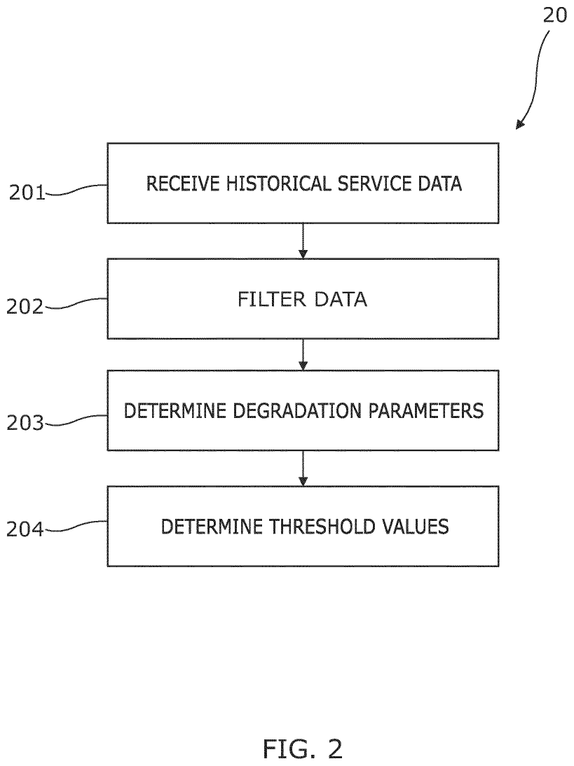

FIG. 2 illustrates the steps of a method 20 performed by the controller 14 to derive or determine threshold values for various different degradation parameters that are analysed to determine a level of degradation of a UPS and associated components. The method 20 may be performed offline using historical, experimental or field service data from sensors or other sources monitoring a fleet or set of UPSs, e.g. operating in different contexts.

Step 201 of the method involves receiving, acquiring or retrieving the data needed to derive the threshold values for the parameters under consideration. In a similar manner to that described above, each UPS in the set of UPSs being used to derive the thresholds may have one or more sensors monitoring the environmental conditions in the vicinity of the respective UPS. In the present example, both temperature and humidity are monitored by the sensors, and the measured values of both over time for each UPS may be stored, e.g. in the cloud. This may be referred to as historical sensor data or historical telemetry data. The controller 14 retrieves the historical sensor data for each UPS in the set from the database in which it is stored. The controller 14 also utilises historical service records of each UPS in the set for the purpose of deriving the threshold values. The historical service records may include information relating to various aspects of each UPS's performance over time, and may be retrievable from a database located locally or remotely, e.g. in the cloud. In particular, the controller 14 may retrieve data from such historical service records indicative of when a particular UPS has suffered unacceptable levels of degradation as a result of environment-related issues, e.g. ambient operating conditions. This may be referred to as historical degradation data. For instance, this can include a timestamp of when a particular UPS has become degraded for this reason.

Collectively, the historical sensor data and historical degradation data may be referred to as historical service data for the set of UPSs used to derive the thresholds.

At step 202 of the method 20, one or more filtering processes may be performed on the historical sensor data prior to deriving the threshold values. Data acquired from such sensors typically includes significant noise and so filtering the data in certain ways can increase the likelihood that derived thresholds accurately reflect parameter values at which degradation levels breach a certain level.

In some cases, the noise can take the form of unfeasible or unrealistic values of measured variables. For instance, some data records may indicate measured humidity being above 100% at certain points, which is clearly unfeasible. One process that may be performed to filter the data may therefore involve removing unfeasible values in the retrieved historical sensor data, such as data that is outside of certain bounds, e.g. physical bounds. Another example may be where an observed rate of change of the values of a measured variable as recorded is not physically realisable. For instance, if there is a frequent, and relatively large, change in humidity in a given day. This may be filtered to obtain values that reflect a slower and average change of the humidity over time.

The retrieved historical sensor data may include asynchronously sample data. As mentioned above, as more sensors are installed to monitor various environmental conditions, the amount of data being captured increases significantly. This leads to increased generation, transmission and storage costs, for instance if the captured data is being stored remotely, e.g. in the cloud.

To address this issue, asynchronous sampling of the sensor data may be utilised. In particular, data may be sampled and transmitted only if there has been a significant enough change from previous records, e.g. a 5% change from a previous record. This means that data may be available at asynchronous times. However, this poses an issue in terms of processing the data. Many existing signal processing methods rely on an assumption of synchronously sampled data being available. Furthermore, the historical sensor data typically has missing data resulting in relatively large data gaps. This then poses an issue that time series analysis of the data becomes challenging.

In view of the above, one filtering process that may be performed on the historical sensor data is to apply a so-called ‘Butterworth filter’. An advantage of a Butterworth filter is that it has no ripples in the pass band and rolls off towards zero in the stopband. While other filters such as a Chebyshev filter has an even faster drop off, it exhibits (undesirable) humps in the stopband (unlike with the Butterworth filter).

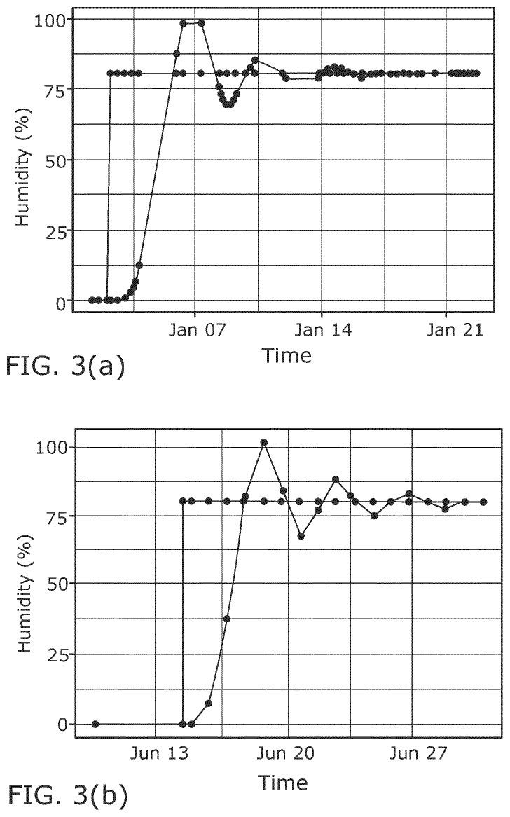

However, as the sensor data being processed may be asynchronously sampled, the Butterworth filter's initial response may be oscillatory in nature and introduce large errors in the filtered output. In particular, there may be a significant delay in waiting for the filter to settle out to the correct value, meaning that the output is delayed. FIGS. 3(a) and 3(b) illustrate two examples in which asynchronously sampled humidity sensor data was input to the filter. In both cases, it is seen that the filter took 8 to 10 days to settle and provide output with a minimum error.

To address this delay issue (which makes it difficult to process data in real time), a further filtering process that may be performed to the historical sensor data is to pad non-uniform sampled data to the (original) received historical sensor data. This non-uniform sampled data is generated randomly for a selected time period. Given the settling time of the experimental examples illustrated in FIGS. 3(a) and 3(b), the selected time period may for instance be around 14 days, or any other suitable time period. The received historical sensor data is then appended to the generated non-uniform sampled data and the Butterworth filter is applied to the combined data. The padding is therefore equivalent to starting the filter early—by injecting a data signal before the first data point of the data of interest—so that by the time the data of interest is being filtered, i.e. the historical sensor data, the Butterworth filter should have settled to provide output with minimum error.

After the Butterworth filter has been applied to the combined data, the output response corresponding to the padded data is removed from the output from the Butterworth filter prior to further analysis. This may be referred to as de-padding the filter output. This is to ensure that any thresholds that are derived are not based on randomly generated data that does not reflect when UPS degradation is occurring as a result of environmental conditions.

At step 203 of the method 20, one or more parameters that may be used as an indication of one or more types of degradation or wear to a UPS or associated components may be extracted from the (filtered) historical sensor data. These parameters may be referred to as degradation parameters.

The degradation parameters of interest may include real-time or instantaneous parameters. That is, the value of such parameters at a given moment in time is useful in determining a level of degradation of a UPS. The (ambient) temperature and humidity may themselves be regarded as degradation parameters.

The inventors of the presently disclosed subject matter have identified further parameters that may be derived from the available sensor data that are useful in identifying environmental conditions that contribute to degradation of a UPS, e.g. different types of degradation or wear modes than may be identified with temperature and humidity alone.

One such parameter is a dew point temperature. This is defined as the temperature at which moisture in the air starts to condensate. The dew point temperature is determined based on (ambient) temperature and humidity. One way in which dew point temperature T_{d} may be determined is:

$${T}_{d} = 243.5 \times \frac{ln \frac{s}{6 \text{.112}}}{17.67 - ln \frac{s}{6.112}}$$

$$s = \frac{{e}_{s} \times RH}{100}$$

$${e}_{s} = 6.112 \times \frac{17.67 T}{{e}^{T + 243.5}}$$

where T temperature and RH is relative humidity.

Another such parameter is equilibrium moisture content (EMC), which is the moisture content at which a material is neither gaining nor losing moisture. This parameter can be indicative of when corrosion of metal is likely to occur. One way in which EMC may be determined is as follows:

$$E M C = \frac{1800}{W} \times ( \frac{kRH}{1 - kRH} + \frac{{k}_{1} kRH + 2 {k}_{1} {k}_{2} {k}^{2} {RH}^{2}}{1 + {k}_{1} kRH + {k}_{1} {k}_{2} {k}^{2} {RH}^{2}} )$$

$$W = 33 \; 0 + 0.452 T + 0.00415 {T}^{2}$$

$$k = 0. 791 + 4.63 \times 1 {0}^{- 4} T - 8.44 \times 1 {0}^{- 7} {T}^{2}$$

$${k}_{1} = 0.791 + 7.75 \times 1 {0}^{- 4} T - 9.35 \times 1 {0}^{- 5} {T}^{2}$$

$${k}_{2} = 1.09 + 2.84 \times 1 {0}^{- 2} T - 9.04 \times 1 {0}^{- 5} {T}^{2}$$

A further such parameter that has been identified to be useful for determining degradation is the difference between the dew point temperature and the (ambient) temperature.

The inventors of the presently disclosed subject matter have identified that parameters that are indicative of longer-term build-up of stress on UPS components as a result of environmental conditions (rather than just using parameters reflecting instantaneous or shorter-term environmental conditions as outlined above) are useful indicators of UPS degradation. That is, even if instantaneous or real time environmental conditions over a certain time period do not indicate unacceptable levels of degradation at a given point, the cumulative effects of the environmental conditions over the time period may result in high degradation or wear. In other words, as environment stress is a slow acting phenomenon, then notifications based on instantaneous values of parameters may still lead to unplanned downtime events without prior warning. Thus, utilisation of longer-term temperature and humidity measurements allows for an assessment of accumulated stress on UPS components.

These longer term or cumulative degradation parameters that are determined and monitored may include determining the cumulative effects over a defined time period of one or more of the shorter term (real time/instantaneous) degradation parameters outlined above. That is, the cumulative degradation parameters may include one or more of cumulative temperature, humidity, dew point temperature, equilibrium moisture content over the defined time period.

The cumulative stress or degradation parameters may be determined in any suitable manner. For instance, determining a cumulative degradation parameter may include integrating the corresponding real time degradation parameter with respect to time, e.g. using trapezoidal integration, multiplied over the defined time period, such as a particular number of days, e.g. 30 days or any other suitable number of days.

At step 204 of the method 20, a threshold value for each of the degradation parameters of interest is determined. The threshold value for each parameter may be indicative of a value at which an unacceptable level of degradation to a UPS or associated components occurs as a result of the monitored environmental conditions. The unacceptable level of degradation could be a certain level of wear suffered by one or more UPS components, or could be indicative of likely failure of one or more UPS components as a result of environmental conditions in the vicinity of the UPS.

The threshold values are set or defined with respect to the retrieved historical degradation data. That is, values or patterns of the degradation parameters that correspond to historical degradation, or other performance or wear issues, of the UPSs in the defined set are used to define the threshold values. For instance, the threshold values could be set at values corresponding to a (high) degradation point of the UPS components, or set at a suitable value below such a degradation point to allow a suitable error margin. The determined threshold values are then stored in a suitable database accessible by the controller 14 to be used in real time analysis of the UPSs 123.

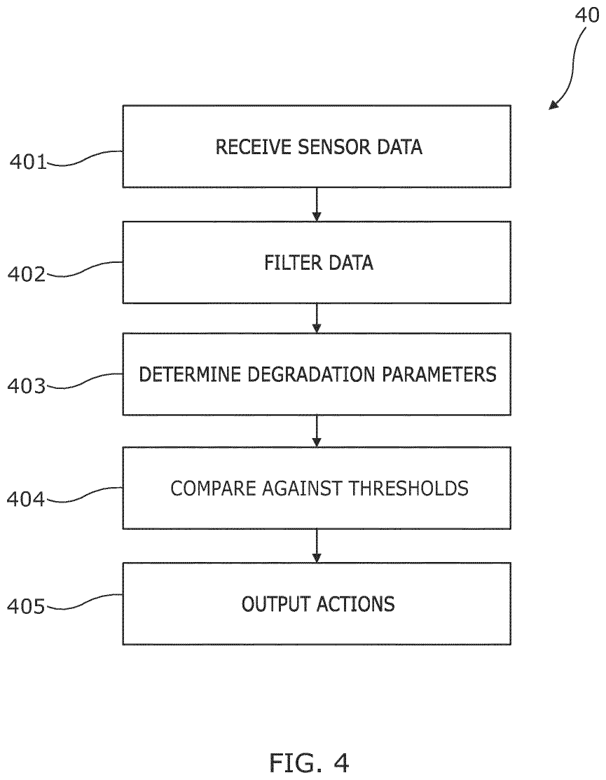

FIG. 4 shows the steps of a method 40 performed by the controller 14 to determine degradation of one or more of the UPS devices 123 during operation. In particular, the method 40 determines whether an unacceptable level of degradation is occurring, or an unacceptable acceleration of degradation is occurring, during operation of the UPS device 123 as a result of environmental conditions. Specifically, the controller 14 uses the (previously) determined threshold values to determine the degradation or damage level of the UPS 123.

Step 401 of the method 40 involves receiving, retrieving or acquiring real-time sensor data that is collected by the sensor 103 associated with the UPS 123 under consideration. In the described example, this data includes measured ambient temperature and humidity; however, it will be understood that only one of these may be included, or further measured environment or ambient measured variables, may be included in different examples. In practice, the real-time data collected by the sensor 103 may be transmitted (e.g. over a wireless network) to a server or database for storage. This transmission may not be performed in real time and, for instance, may be performed as bulk or batch transmissions of data at certain times. The controller 14 may then retrieve the real-time sensor data from the database in which the data is stored in order to perform the subsequent analysis. The controller 14 may therefore be regarded as performing offline processing or analysis of real-time data. Depending on when the real-time sensor data is transmitted to the server or database for storage, the controller 14 can provide insights relatively quickly on UPS degradation during operation.

At step 402 of the method 40, the controller 14 may perform one or more filtering processes on the acquired real-time data. In particular, this may be the same one or more filtering processes applied to the historical data when determining the threshold values for each degradation parameter (step 202 of FIG. 2). That is, the filtering may include removing unfeasible values from the data set, applying a Butterworth filter, and/or padding and de-padding the data set either side of applying the Butterworth filter.

At step 403 of the method 40, the controller 14 determines values of the degradation values of interest based on the (possibly filtered) sensor data. The degradation parameters of interest may the same as those for which threshold values were calculated (step 203 of FIG. 2). The degradation parameters may include real-time or short-term degradation parameters and/or may include cumulative or longer-term degradation parameters, as outlined above.

At step 404 of the method 40, the controller 14 uses the determined degradation parameter values to determine degradation of the UPS 123 under consideration. In particular, the previously-determined threshold values of the degradation parameters are retrieved, e.g. from a database in which they are stored, and the determined degradation parameter values are compared against the respective threshold values. Based on the comparison, the controller 14 determines whether the UPS 123—or one or more specific components of the UPS 123, or any associated components—are suffering an unacceptable level of degradation as a result of the environmental or ambient conditions in which the UPS 123 is operating.

In one example, the controller 14 may determine that an unacceptable level of degradation is occurring if at least one of the degradation parameter values exceeds (or otherwise breaches) the respective threshold value. In other examples, a specified number of degradation parameters may need to breach the respective threshold values before the UPS 123 is deemed to be suffering unacceptable degradation or wear.

At step 405 of the method 40, one or more outputs are generated based on the comparison at step 404. In the event that it is determined that an unacceptable level of degradation is occurring, a warning or alarm may be generated. Such an alarm may be stored in an appropriate database, for instance. Alternatively, or in addition, such an alarm may be transmitted in an appropriate manner to an operator or service personnel. The alarm could be a visual, audio and/or haptic signal as appropriate, thereby notifying the operator that action may need to be taken, e.g. to avoid failure of the UPS 123. In some examples, a control output may be generated to take automatic action in response to an unacceptable level of degradation being determined. For instance, this could include control actions to change the environmental conditions in which the UPS 123 is operating, e.g. activating an air conditioning system in or near the battery cabinet 102, or switching to a different UPS to provide power to the electrical components that require power.

The method 40 may be repeated substantially continuously, e.g. at each time step of the controller/processor, or at defined times or intervals.

Many modifications may be made to the described examples without departing from the scope of the appended claims.

Although the above examples describe one or more UPS devices providing power to electrical components via one or more PDUs, it will be understood that in different examples no PDUs are present or needed.

Although the above examples describe a controller for monitoring a UPS device that provides emergency power to electrical components in a data centre, it will be understood that in different examples the UPS device may be for providing emergency power to electrical components in a different location or for a different application. For instance, the UPS may provide emergency power to different critical infrastructure, such as electrical components/machinery in a hospital or telecommunications infrastructure, or the UPS may provide emergency power to non-critical infrastructure.

The above examples describe a single controller that both: determines the threshold values for the one or more degradation parameters of interest; and, analysing the real-time sensor data to determine degradation of a UPS. However, it will be understood that separate controllers, e.g. at separate locations, may perform these two processes.

Although a battery (or batteries) for powering a UPS are described in the above examples as being part of the (overall) UPS device, such a battery or batteries may be regarded as being separate from the UPS device in different examples. In such examples, it will be understood that the described methods and systems may alternatively or additionally be used to monitor the battery or batteries.

Although the described examples relate to monitoring a UPS device, it will be understood that the described methods and systems may be used for monitoring different types of electrical or electronic devices. For instance, the described methods and systems may be used to monitor one or more components of a data centre, e.g. a transformer, switchgear, and/or one or more hard disks. Another example in which the described methods and systems may be used are for monitoring an electrical substation in a manufacturing plant. The described methods and systems may be used for monitoring any suitable type of electrical or electronic device.

1. A computer-implemented method for determining degradation of an electrical device, the method comprising:
retrieving historical service data for a set of one of more electrical devices, the historical service data including, for each electrical device in the set:
historical sensor data indicative of environmental conditions in the vicinity of the respective electrical device during operation, the sensor data including data indicative of at least measured temperature and measured humidity; and,
historical degradation data indicative of degradation of the respective electrical device;
determining, based on the historical sensor data, historical values of one or more degradation parameters that are indicative of electrical device degradation caused by environmental conditions;
determining, based on the historical values of the one or more degradation parameters and on the historical degradation data, a threshold value for each degradation parameter, the threshold value being a value of the respective degradation parameter above which an unacceptable level of degradation occurs; and,
using the determined one or more threshold values to determine whether an unacceptable level of degradation is occurring during operation of the electrical device.

2. A method according to claim 1, wherein using the determined one or more threshold values comprises:
receiving, from at least one sensor in the vicinity of the electrical device, sensor data indicative of environmental conditions in the vicinity of the electrical device, the sensor data including data indicative of at least measured temperature and measured humidity;
determining, based on the received sensor data, a value of each of the degradation parameters; and,
comparing each determined value against the respective threshold value to determine whether an unacceptable level of degradation is occurring.

3. A method according to claim 2, wherein an unacceptable level of degradation is determined to be occurring if at least one of the determined values exceeds the respective threshold value.

4. A method according to claim 2, wherein, prior to determining the values of each of the degradation parameters, the method comprises applying one or more data filtering processes to the received sensor data, the values of each of the degradation parameters being determined based on the filtered data.

5. A method according to claim 4, wherein the one or more data filtering processes comprises removing unfeasible data included in the received sensor data.

6. A method according to claim 4, wherein the one or more data filtering processes comprises applying a low pass Butterworth filter to the received sensor data.

7. A method according to claim 6, wherein the received sensor data comprises asynchronously sampled data, and wherein the one or more data filtering processes comprises:
prior to applying the low pass Butterworth filter, appending the received sensor data to a padding data signal comprising non-uniform sampled data to obtain a combined data signal, the low pass Butterworth filter being applied to the combined data signal; and,
after applying the low pass Butterworth filter, removing the output response from the low pass Butterworth filter corresponding to the padding data signal prior to determining the values of each of the degradation parameters.

8. A method according to claim 1, wherein, prior to determining the historical values of each of the degradation parameters, the method comprises applying one or more data filtering processes to the retrieved historical sensor data, the historical values of each of the degradation parameters being determined based on the filtered data.

9. A method according to claim 1, wherein the one or more degradation parameters includes one or more real-time degradation parameters that include at least one of:
a dew point temperature;
an equilibrium moisture content; and,
a difference between the dew point temperature and the measured temperature.

10. A method according to claim 1, wherein the one or more degradation parameters includes at least one cumulative degradation parameter indicative of cumulative electrical device degradation over a defined time period caused by environmental conditions over the defined time period.

11. A method according to claim 10, wherein determining the value of each cumulative degradation parameter comprises:
retrieving sensor data received from the at least one sensor in the vicinity of the device over the defined time period, wherein the device is an Uninterruptible Power Supply (UPS) device;
determining values of a real-time degradation parameter over the defined time period based on the retrieved sensor data; and,
integrating the real-time degradation parameter values with respect to time to determine the associated cumulative degradation parameter value.

12. A method according to claim 10, wherein each parameter indicative of cumulative Uninterruptible Power Supply (UPS) device degradation is one of:
cumulative temperature over the defined time period;
cumulative humidity over the defined time period;
cumulative dew point temperature over the defined time period; and,
cumulative equilibrium moisture content over the defined time period.

13. A method according to claim 1, wherein the method is implemented by one or more processors located remotely from the electrical device.

14. A method according to claim 1, wherein, if it is determined that an unacceptable level of degradation is occurring during operation of the electrical device, then the method comprises generating an alarm signal.

15. (canceled)

16. A method according to claim 14, wherein, if it is determined that an unacceptable level of degradation is occurring during operation of the electrical device, then the method comprises generating a control signal to control one or more devices for mitigating the occurrence of electrical device degradation; optionally, wherein the control signal causes an air conditioning unit in the vicinity of the electrical device to activate.

17. A method according to claim 1, wherein the electrical device is an Uninterruptible Power Supply (UPS) device.

18. A method according to claim 1, wherein the electrical device is:
a battery, optionally a battery for providing power to an Uninterruptible Power Supply (UPS);
one or more components of a data centre, optionally wherein the components includes a transformer, switchgear, and/or one or more hard disks; or,
an electrical substation in a manufacturing plant.

19. (canceled)

20. A computer-implemented method for determining degradation of an electrical device, the method comprising:
receiving, from at least one sensor in the vicinity of the electrical device, sensor data indicative of environmental conditions in the vicinity of the electrical device, the sensor data including data indicative of at least measured temperature and measured humidity;
determining, based on the received sensor data, values of one or more degradation parameters that are indicative of electrical device degradation caused by environmental conditions; and,
comparing each determined value against a respective defined threshold value to determine whether an unacceptable level of degradation is occurring,
wherein the one or more degradation parameters includes at least one cumulative degradation parameter indicative of cumulative electrical device degradation over a defined time period caused by environmental conditions over the defined time period.

21. (canceled)

22. A system for determining degradation of an electrical device, the system comprising one or more processors, the system being configured to:
retrieve historical service data for a set of one of more electrical devices, the historical service data including, for each electrical device in the set:
historical sensor data indicative of environmental conditions in the vicinity of the respective electrical device during operation, the sensor data including data indicative of at least measured temperature and measured humidity; and,
historical degradation data indicative of degradation of the respective electrical device;
determine, based on the historical sensor data, historical values of one or more degradation parameters that are indicative of electrical device degradation caused by environmental conditions;
determine, based on the historical values of the one or more degradation parameters and on the historical degradation data, a threshold value for each degradation parameter, the threshold value being a value of the respective degradation parameter above which an unacceptable level of degradation occurs; and,
use the determined one or more threshold values to determine whether an unacceptable level of degradation is occurring during operation of the electrical device.

23. A system according to claim 22, the one or more electrical devices are Uninterruptible Power Supply (UPS) devices.
